(19) United States
(12) Patent Application Publication
(10) Pub. No.: US 2020/0217728 A1
(43) Pub. Date: Jul. 9, 2020

(54) A HEAT-FLUX SENSOR

(71) Applicant: Lappeenrannan-Lahden teknillinen yliopisto LUT, LAPPEENRANTA (FI)

(72) Inventors: Mikko KUISMA, LAPPEENRANTA (FI); Antti IMMONEN, LAPPEENRANTA (FI); Saku LEVIKARI, LAPPEENRANTA (FI)

(21) Appl. No.: 16/647,254

(22) PCT Filed: Aug. 21, 2018
(86) PCT No.: PCT/FI2018/050589

§ 371 Date: Mar. 13, 2020

(30) Foreign Application Priority Data
Sep. 15, 2017 (FI) 20175819

(51) Int. Cl. G01K 17/00; G01K 7/08; H01L 35/32; H01L 35/20; H01L 35/02

(52) U.S. Cl. CPC G01K 17/00; G01K 7/08; H01L 35/02; H01L 35/20; H01L 35/32

(57) ABSTRACT

A heat-flux sensor includes first and second pieces made of different materials and arranged to constitute a contact junction for generating electromotive force in response to a temperature difference between the first and second pieces. The heat-flux sensor includes a first electric conductor connected to the first piece and a second electric conductor connected to the second piece so that the electromotive force is detectable from between ends of the first and second electric conductors. The mass and the heat capacity of the second piece are significantly greater than those of the first piece so that a heat-flux across the contact junction causes a temperature difference between the first and second pieces but no significant temperature change in the second piece. Thus, the electromotive force caused by the temperature difference is indicative of the heat-flux.

### TECHNICAL FIELD

The disclosure relates generally to heat-flux sensors for measuring thermal energy transfer directly. More particularly, the disclosure relates to a structure of a heat-flux sensor and to a system comprising a heat-flux sensor.

### BACKGROUND

Heat-flux sensors are used in various power-engineering applications where local heat-flux measurements can be more important than temperature measurements. A heat-flux sensor can be based on multiple thermoelectric junctions so that tens, hundreds, or even thousands of thermoelectric junctions are connected in series. For another example, a heat-flux sensor can be based on one or more anisotropic elements where electromotive force is created from a heat-flux by the Seebeck effect. Because of the anisotropy, a temperature gradient has components in two directions: along and across to a heat-flux through the sensor. Electromotive force is generated proportional to the temperature gradient component across to the heat-flux. The anisotropy can be implemented with suitable anisotropic material such as for example single-crystal bismuth. A drawback of heat-flux sensors based on single-crystal bismuth is that they are not suitable for heat-flux measurements in high temperatures because of the low melting point of bismuth. Another option for implementing the anisotropy is a multilayer structure where layers are oblique with respect to a surface of a heat-flux sensor for receiving a heat-flux. Details of heat-flux sensors based on a multilayer structure can be found from for example the publication: “Local Heat Flux Measurement in a Permanent Magnet Motor at No Load”, Hanne K. Jussila, Andrey V. Mityakov, Sergey Z. Sapozhnikov, Vladimir Y. Mityakov and Juha Pyrhönen, Institute of Electrical and Electronics Engineers “IEEE” Transactions on Industrial Electronics, Volume: 60, pp. 4852-4860, 2013.

The above-described known heat-flux sensors based on multiple thermoelectric junctions or anisotropy are, however, not free from challenges. One of the challenges is related to unit price which may be high in conjunction with some heat-flux sensor types. Moreover, in many cases, there can be a further challenge related to installation of a heat-flux sensor on a device or a system being monitored because the heat-flux sensor needs room and furthermore there can be a need for fastening means for attaching the heat-flux sensor on a structure of the device or system in a reliable way. Furthermore, a limited mechanical durability and/or heat resistance of many heat-flux sensors can be a factor that limits the use of heat-flux sensors in many applications. Challenges of the kind mentioned above raise the threshold of integrating heat-flux sensors to many devices and systems where heat-flux measurements would be, however, useful.

### SUMMARY

The following presents a simplified summary in order to provide a basic understanding of some aspects of various invention embodiments. The summary is not an extensive overview of the invention. It is neither intended to identify key or critical elements of the invention nor to delineate the scope of the invention. The following summary merely presents some concepts of the invention in a simplified form as a prelude to a more detailed description of exemplifying embodiments of the invention.

In this document, the word “geometric” when used as a prefix means a geometric concept that is not necessarily a part of any physical object. The geometric concept can be for example a geometric point, a straight or curved geometric line, a geometric plane, a non-planar geometric surface, a geometric space, or any other geometric entity that is zero, one, two, or three dimensional.

In accordance with the invention, there is provided a new heat-flux sensor for measuring thermal energy transfer.

A heat-flux sensor according to the invention comprises:
first and second pieces made of different materials and arranged to constitute a contact junction of the materials for generating electromotive force in response to a temperature difference between the first and second pieces, and
a first electric conductor connected to the first piece and a second electric conductor connected to the second piece, the electromotive force being detectable from between ends of the first and second electric conductors.

The mass and the heat capacity of the second piece are greater than the mass and the heat capacity of the first piece so that a temperature difference between the first and second pieces and caused by a heat-flux across the contact junction from the first piece to the second piece is greater than a temperature increase caused by the heat-flux to a place of the second piece where the second electric conductor is connected to the second piece. Thus, the heat-flux causes the above-mentioned temperature difference but no significant temperature increase in the second piece. Therefore, the electromotive force caused by the temperature difference is indicative of the heat-flux.

In a heat-flux sensor according to an exemplifying and non-limiting embodiment of the invention, the second piece is a part of a device or a system from which the heat-flux is measured. In this exemplifying and non-limiting case, the second piece can be for example but not necessarily a cylinder head of an internal combustion engine, a wall of a combustion chamber of a turbine engine, or a wall of a reactor chamber or a pipeline of a process industry installation. The first piece can be for example a thin sheet of material, e.g. metal, on a surface of the second piece or a thin wire on a surface of the second piece. Thus, the heat-flux sensor can be cost effective and mechanically durable. Increased cost-efficiency and durability of heat-flux sensing also lowers the threshold of integrating heat-flux measurements to devices and systems where there have previously been hindrances in doing so. Furthermore, the second piece of a heat-flux sensor can be a part of human instrumentation such as a monitoring and/or measuring device attached with a wrist or chest band. In this exemplifying case, a heat-flux sensor according to an exemplifying and non-limiting embodiment of the invention can be arranged to measure a heat-flux generated by a human.

In accordance with the invention, there is provided also a new system that comprises:
a device, e.g. an integrated circuit, to be cooled, and
a heat-flux sensor according to an exemplifying and non-limiting embodiment of the invention for cooling the device and for measuring a heat-flux arriving from the device.

In the above-mentioned system, the second piece of the heat-flux sensor is a heat-sink element and the first piece of the heat flux sensor is between the heat-sink element and the device to be cooled. Thus, the heat-sink element acts not only as a heat-sink but also as a part of the heat-flux sensor for measuring the heat-flux arriving from the device.

Various exemplifying and non-limiting embodiments of the invention are described in accompanied dependent claims.

Various exemplifying and non-limiting embodiments of the invention both as to constructions and to methods of operation, together with additional objects and advantages thereof, will be best understood from the following description of specific exemplifying and non-limiting embodiments when read in conjunction with the accompanying drawings.

The verbs “to comprise” and “to include” are used in this document as open limitations that neither exclude nor require the existence of unrecited features. The features recited in dependent claims are mutually freely combinable unless otherwise explicitly stated. Furthermore, it is to be understood that the use of “a” or “an”, i.e. a singular form, throughout this document does not exclude a plurality.

### BRIEF DESCRIPTION OF THE FIGURES

Exemplifying and non-limiting embodiments of the invention and their advantages are explained in greater detail below in the sense of examples and with reference to the accompanying drawings, in which:

FIG. 1 illustrates schematically a heat-flux sensor according to an exemplifying and non-limiting embodiment of the invention,

FIG. 2 illustrates schematically a heat-flux sensor according to an exemplifying and non-limiting embodiment of the invention,

FIG. 3 illustrates a heat-flux sensor according to an exemplifying and non-limiting embodiment of the invention,

FIG. 4 illustrates a heat-flux sensor according to an exemplifying and non-limiting embodiment of the invention, and

FIG. 5 illustrates a system according to an exemplifying and non-limiting embodiment of the invention.

### DESCRIPTION OF THE EXEMPLIFYING EMBODIMENTS

The specific examples provided in the description below should not be construed as limiting the scope and/or the applicability of the accompanied claims. Lists and groups of examples provided in the description are not exhaustive unless otherwise explicitly stated.

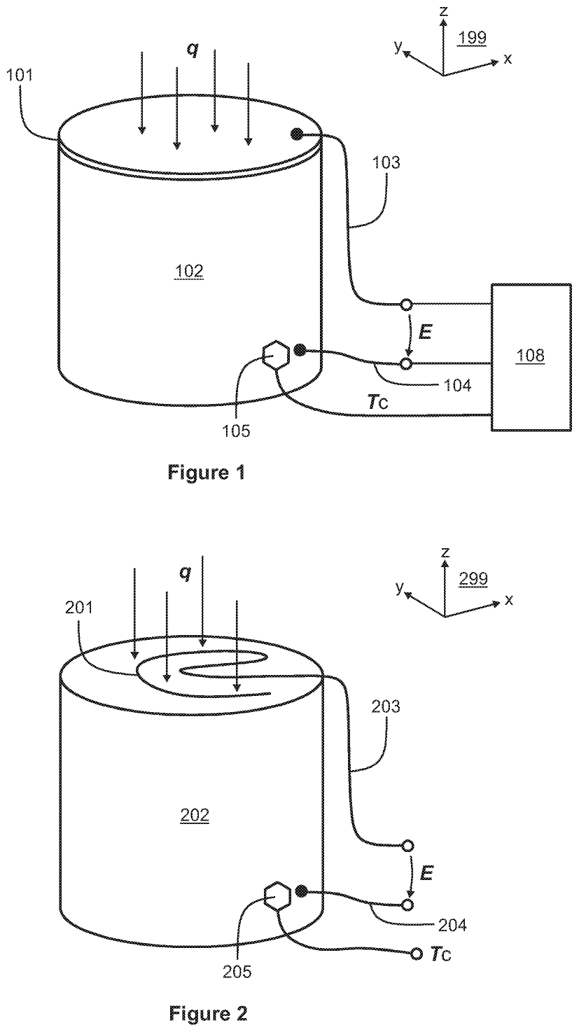

FIG. 1 illustrates schematically a heat-flux sensor according to an exemplifying and non-limiting embodiment of the invention. The heat-flux sensor comprises a first piece 101 and a second piece 102 so that the first piece 101 is made of different material than the second piece 102. It is worth noting that FIG. 1 is only a schematic illustration and, in practice, the second piece 102 can be for example a cylinder head of an internal combustion engine, a wall of a combustion chamber of a turbine engine, or a wall of a reactor chamber or a pipeline of a process industry installation, or a part of some other device or system. The first and second pieces 101 and 102 are arranged to constitute a contact junction of two materials of differing thermoelectric properties. The heat-flux sensor comprises a first electric conductor 103 connected to the first piece 101 and a second electric conductor 104 connected to the second piece 102. The heat-flux sensor is based on thermoelectric effect, i.e. the Seebeck effect, at the contact junction of the two materials. A temperature difference between the first and second pieces 101 and 102 generates electromotive force E which is detectable from between ends of the first and second electric conductors 103 and 104. The first piece 101 can be made of for example aluminum, copper, molybdenum, constantan, or nichrome. The second piece 102 can be made of for example steel, aluminum, copper, molybdenum, constantan, or nichrome. The materials of the first and second pieces 101 and 102 are advantageously chosen so that the materials are thermoelectrically dissimilar to maximize the generation of the electromotive force E.

The mass and the heat capacity, J/K, of the second piece 102 are significantly greater than the mass and the heat capacity of the first piece 101 so that a temperature difference between the first and second pieces 101 and 102 and caused by a heat-flux q across the contact junction from the first piece 101 to the second piece 102 is significantly greater than a temperature increase caused by the heat-flux q to a place of the second piece 102 where the second electric conductor 104 is connected to the second piece 102. Thus, the heat-flux q causes the above-mentioned temperature difference but no significant temperature increase in the second piece 102. Therefore, the electromotive force E caused by the temperature difference is indicative of the heat-flux q. In FIG. 1, the heat-flux q is illustrated with vectors each having a direction opposite to the positive z-direction of a coordinate system 199, but in reality the directions of vectors depicting the heat-flux q can deviate from the case shown in FIG. 1.

The mass of the second piece 102 is advantageously at least ten times the mass of the first piece 101. More advantageously, the mass of the second piece 102 is at least fifty times the mass of the first piece 101. Yet more advantageously, the mass of the second piece 102 is at least one hundred times the mass of the first piece 101. In the exemplifying heat-flux sensor illustrated in FIG. 1, the first piece 101 is a thin material sheet on a surface of the second piece 102. The thickness of the material sheet can be e.g. from 0.001 mm to 1 mm. Therefore, in practical applications where the second piece 102 can be e.g. a cylinder head, the mass of the second piece 102 can be thousands of times the mass of the first piece 101.

The above-described heat-flux sensor can be considered a differential thermocouple heat-flux sensor where a point of higher temperature, i.e. the hot reference, is formed in the mechanical and electrical contact between the first and second pieces 101 and 102. As the second piece 102 is large in terms of mass and heat capacity, i.e. semi-infinite, the temperature of the second piece 102 remains relatively constant. The point of lower temperature, i.e. the cold reference, is placed in this semi-infinite second piece 102. The temperature difference between the above-mentioned hot reference and the cold reference generates voltage which is directly related to the heat flux q. To provide information for improving accuracy and/or for compensating variations in the temperature of the second piece 102, an additional temperature sensor 105 can be implemented. The heat-flux sensor may further comprise a processing system 108 which is configured to produce an estimate of the heat flux q based on the electromotive force E and the temperature T, measured with the temperature sensor 105.

FIG. 2 illustrates schematically a heat-flux sensor according to an exemplifying and non-limiting embodiment of the invention. The heat-flux sensor comprises a first piece 201 and a second piece 202 so that the first piece 201 is made of different material than the second piece 202. The first and second pieces 201 and 202 are arranged to constitute a contact junction of two materials of differing thermoelectric properties. The heat-flux sensor comprises a first electric conductor 203 connected to the first piece 201 and a second electric conductor 204 connected to the second piece 202. A temperature difference between the first and second pieces 201 and 202 generates electromotive force E which is detectable from between ends of the first and second electric conductors 203 and 204.

In the exemplifying heat-flux sensor illustrated in FIG. 2, the first piece 201 is a thin wire on a surface of the second piece 202. The diameter of the wire can be e.g. from 0.01 mm to 1 mm. Therefore, in practical applications where the second piece 202 can be e.g. a cylinder head, the mass of the second piece 202 can be thousands of times the mass of the first piece 201. The above-mentioned first electric conductor 203 can be a part of the wire constituting the first piece 201, i.e. no joints are needed between the first piece 201 and the first electric conductor 203. As the mass and the heat capacity of the second piece 202 are significantly greater than the mass and the heat capacity of the first piece 201, a heat-flux q causes a temperature difference between the first and second pieces 201 and 202 but no significant temperature increase in the second piece 102. Therefore, the electromotive force E caused by the temperature difference is indicative of the heat-flux q. In FIG. 2, the heat-flux q is illustrated with vectors each having a direction opposite to the positive z-direction of a coordinate system 299, but in reality the directions of vectors depicting the heat-flux q can deviate from the case shown in FIG. 2. To provide information for improving accuracy and/or for compensating variations in the temperature of the second piece 202, the heat-flux sensor may further comprise a temperature sensor 205 for measuring the temperature of the second piece 202.

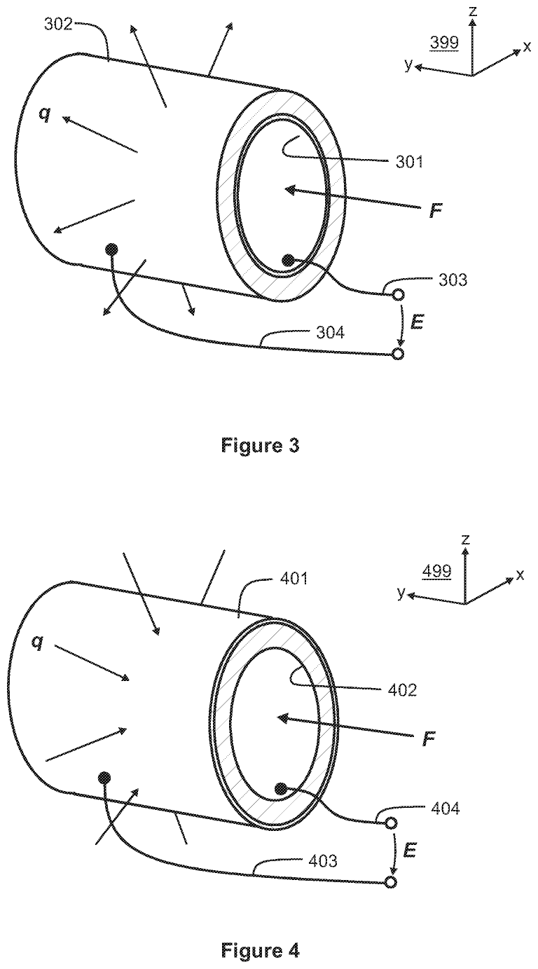

FIG. 3 illustrates a heat-flux sensor according to an exemplifying and non-limiting embodiment of the invention. The heat-flux sensor comprises a first piece 301 and a second piece 302 so that the first piece 301 is made of different material than the second piece 302. In this exemplifying case, the second piece 302 is a tube for conducting fluid F in a direction parallel with the y-axis of a coordinate system 399 and the first piece 301 is a thin material sheet on the inner surface of the tube. It is, however, also possible that the first piece is a thin wire on the inner surface of the tube. The first and second pieces 301 and 302 are arranged to constitute a contact junction of two materials of differing thermoelectric properties. The heat-flux sensor comprises a first electric conductor 303 connected to the first piece 301 and a second electric conductor 304 connected to the second piece 302. A temperature difference between the first and second pieces 301 and 302 generates electromotive force E which is detectable from between ends of the first and second electric conductors 303 and 304. As the first piece 301 is on the inner surface of the tube, the heat-flux sensor is suitable for measuring a heat-flux q flowing from inside the tube to outside the tube via the wall of the tube. In FIG. 3, the heat-flux q is illustrated with radially directed vectors pointing away from the tube, but in reality the directions of vectors depicting the heat-flux q can deviate from the case shown in FIG. 3.

FIG. 4 illustrates a heat-flux sensor according to an exemplifying and non-limiting embodiment of the invention. The heat-flux sensor comprises a first piece 401 and a second piece 402 so that the first piece 401 is made of different material than the second piece 402. In this exemplifying case, the second piece 402 is a tube for conducting fluid F in a direction parallel with the y-axis of a coordinate system 499 and the first piece 401 is a thin material sheet on the outer surface of the tube. It is, however, also possible that the first piece is a thin wire on the outer surface of the tube. The heat-flux sensor comprises a first electric conductor 403 connected to the first piece 401 and a second electric conductor 404 connected to the second piece 402. A temperature difference between the first and second pieces 401 and 402 generates electromotive force E which is detectable from between ends of the first and second electric conductors 403 and 404. As the first piece 401 is on the outer surface of the tube, the heat-flux sensor is suitable for measuring a heat-flux q flowing from outside the tube to inside the tube via the wall of the tube. In FIG. 4, the heat-flux q is illustrated with radially directed vectors pointing towards the tube, but in reality the directions of vectors depicting the heat-flux q can deviate from the case shown in FIG. 4.

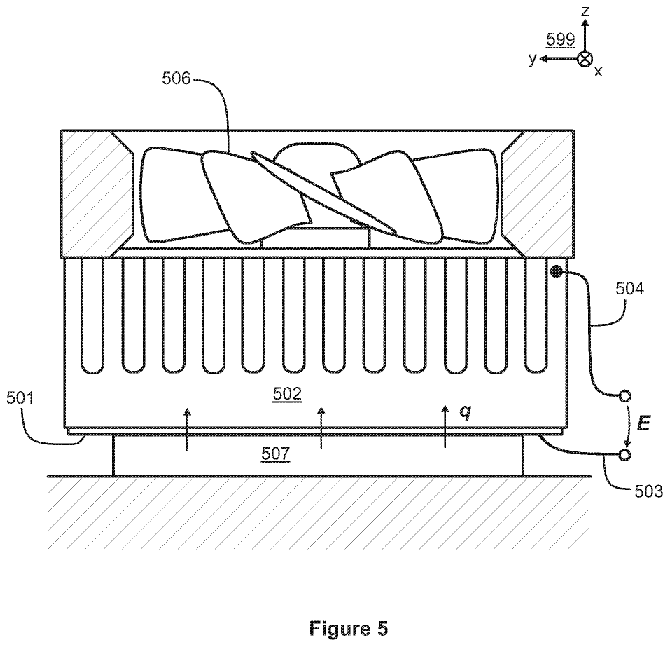

FIG. 5 illustrates a system according to an exemplifying and non-limiting embodiment of the invention. The system comprises a device 507 to be cooled and a heat-flux sensor according to an exemplifying and non-limiting embodiment of the invention for cooling the device 507 and for measuring a heat-flux q arriving from the device. The device 506 can be for example an integrated circuit such as e.g. a processor. The heat-flux sensor comprises a first piece 501 and a second piece 502 so that the first piece 501 is made of different material than the second piece 502. In this exemplifying case, the second piece 502 is a heat-sink element for cooling the device 507 and the first piece 501 is a thin material sheet on an outer surface of the second piece 502 so that the first piece 501 is between the second piece 502 and the device 507 being cooled. The heat-flux sensor comprises a first electric conductor 503 connected to the first piece 501 and a second electric conductor 504 connected to the second piece 502. A temperature difference between the first and second pieces 501 and 502 generates electromotive force E which is detectable from between ends of the first and second electric conductors 503 and 504. As the first piece 501 is between the device 507 and the second piece 502, the heat-flux sensor is suitable for measuring the heat-flux q flowing from the device 507 to the second piece 502. In FIG. 5, the heat-flux q is illustrated with vectors each having the positive z-direction of a coordinate system 599, but in reality the directions of vectors depicting the heat-flux q can deviate from the case shown in FIG. 5.

In the system illustrated in FIG. 5, the heat-sink element acts not only as a heat-sink but also as a part of the heat-flux sensor for measuring the heat-flux q arriving from the device 507. The system may further comprise a fan 506 for moving cooling air between cooling fins of the heat sink element.

The specific examples provided in the description given above should not be construed as limiting the applicability and/or interpretation of the appended claims. It is to be noted that lists and groups of examples given in this document are non-exhaustive lists and groups unless otherwise explicitly stated.

1. A heat-flux sensor comprising:
first and second pieces made of different materials and arranged to constitute a contact junction of the materials for generating electromotive force in response to a temperature difference between the first and second pieces, and
a first electric conductor connected to the first piece and a second electric conductor connected to the second piece, the electromotive force being detectable from between ends of the first and second electric conductors,
wherein a mass and a heat capacity of the second piece are greater than a mass and a heat capacity of the first piece so that the temperature difference between the first and second pieces and caused by a heat-flux across the contact junction from the first piece to the second piece is greater than a temperature increase caused by the heat-flux to a place of the second piece where the second electric conductor is connected to the second piece.

2. The heat-flux sensor according to claim 1, wherein the mass of the second piece is at least ten times the mass of the first piece.

3. The heat-flux sensor according to claim 1, wherein the mass of the second piece is at least fifty times the mass of the first piece.

4. The heat-flux sensor according to claim 1, wherein the mass of the second piece is at least one hundred times the mass of the first piece.

5. The heat-flux sensor according to claim 1, wherein the heat-flux sensor further comprises a temperature sensor for measuring temperature of the second piece.

6. The heat-flux sensor according to claim 1, wherein the first piece is made of one of the following metals and the second piece is made of another one of the following metals: steel, aluminum, copper, molybdenum, constantan, nichrome.

7. The heat-flux sensor according to claim 1, wherein the first piece is a material sheet on a surface of the second piece.

8. The heat-flux sensor according to claim 1, wherein the first piece is a wire on a surface of the second piece.

9. The heat-flux sensor according to claim 8, wherein the first electric conductor is a part of the wire constituting the first piece.

10. The heat-flux sensor according to claim 1, wherein the second piece is a tube for conducting fluid and the first piece is on a surface of the tube.

11. The heat-flux sensor according to claim 10, wherein the first piece is on an inner surface of the tube and the heat-flux sensor is suitable for measuring the heat-flux flowing from inside the tube to outside the tube via a wall of the tube.

12. The heat-flux sensor according to claim 10, wherein the first piece is on an outer surface of the tube and the heat-flux sensor is suitable for measuring the heat-flux flowing from outside the tube into the tube via a wall of the tube.

13. The heat-flux sensor according to claim 1, wherein the second piece (502) is a heat-sink element for cooling a device.

14. The heat-flux sensor according to claim 13, wherein the heat-flux sensor further comprises a fan for moving cooling air between cooling fins of the heat sink element.

15. A system comprising:
a device to be cooled, and
a heat-flux sensor for cooling the device and for measuring a heat-flux arriving from the device, the first piece being between the second piece and the device,
wherein the heat-flux sensor comprises:
first and second pieces made of different materials and arranged to constitute a contact junction of the materials for generating electromotive force in response to a temperature difference between the first and second pieces, and
a first electric conductor connected to the first piece and a second electric conductor connected to the second piece, the electromotive force being detectable from between ends of the first and second electric conductors,
wherein a mass and a heat capacity of the second piece are greater than a mass and a heat capacity of the first piece so that the temperature difference between the first and second pieces and caused by a heat-flux across the contact junction from the first piece to the second piece is greater than a temperature increase caused by the heat-flux to a place of the second piece where the second electric conductor is connected to the second piece.

16. The heat-flux sensor according to claim 2, wherein the heat-flux sensor further comprises a temperature sensor for measuring temperature of the second piece.

17. The heat-flux sensor according to claim 3, wherein the heat-flux sensor further comprises a temperature sensor for measuring temperature of the second piece.

18. The heat-flux sensor according to claim 4, wherein the heat-flux sensor further comprises a temperature sensor for measuring temperature of the second piece.

19. The heat-flux sensor according to claim 2, wherein the first piece is made of one of the following metals and the second piece is made of another one of the following metals: steel, aluminum, copper, molybdenum, constantan, nichrome.

20. The heat-flux sensor according to claim 3, wherein the first piece is made of one of the following metals and the second piece is made of another one of the following metals: steel, aluminum, copper, molybdenum, constantan, nichrome.
